(19) United States
(12) Patent Application Publication
(10) Pub. No.: US 2026/0068459 A1
(43) Pub. Date: Mar. 5, 2026

(54) DISPLAY DEVICE

(71) Applicant: LG Display Co., Ltd., Seoul (KR)

(72) Inventors: Daehee Kim, Gyeonggi-do (KR); JoonYoung Heo, Gyeonggi-do (KR)

(21) Appl. No.: 19/271,951

(22) Filed: Jul. 17, 2025

(30) Foreign Application Priority Data
Sep. 2, 2024 (KR) 10-2024-0118366

(51) Int. Cl. H10K 59/131; H10K 59/80

(52) U.S. Cl. CPC H10K 59/131; H10K 59/80521

(57) ABSTRACT

A display device is provided, the display device including: a plurality of pixels including a circuit area and a transmission area; a plurality of sub-pixels disposed in each of the plurality of pixels and disposed in the circuit area; a voltage line disposed in the circuit area and supplying a voltage; and a plurality of connection lines disposed in the circuit area and electrically connected to the voltage line, wherein each of the plurality of sub-pixels includes a first cathode and a second cathode spaced apart from each other, and wherein the voltage line supplies the voltage to the first cathode through any one of the plurality of connection lines, and supplies the voltage to the second cathode through the other ones of the plurality of connection lines.

### CROSS-REFERENCE TO RELATED APPLICATIONS

Pursuant to 35 U.S.C. § 119(a), this application claims the benefit of an earlier filing date and right of priority to Korean Patent Application No. 10-2024-0118366, filed in the Republic of Korea on Sep. 2, 2024, the disclosure of which is hereby incorporated by reference in its entirety.

### TECHNICAL FIELD

The present disclosure relates to a display device.

### BACKGROUND

With the development of information technology, many related technologies have been developed in the field of display devices for visually displaying information, such as text, images, video, or graphical data. A display device is an output device that converts electrical signals into visible light patterns, typically using an array of pixels composed of sub-pixels.

### SUMMARY

A display device can be used as a laptop, a tablet, a smart phone, a portable display device, or a portable information device display screen in addition to a display screen of a television or a monitor. With the development of capture, camera, and sensing technology, a display device may provide various photographing or sensing functions in addition to an image display. Accordingly, a display device may include an electronic device such as a camera or a sensor.

Among the various types of display devices, an organic light emitting display device is of the self-luminous types, has superior viewing angles and contrast ratios compared to liquid crystal displays, is lightweight and thin because a separate backlight is typically optional, and can have lower power consumption compared to other types of display devices. In addition, organic light emitting display devices have advantages of low voltage driving, fast response speed, and low manufacturing cost.

In the process of forming alight emitting device of an organic light emitting display device, external foreign matter may be introduced from an external environment. Specifically, the light emitting device may be formed by sequentially depositing an anode, a light emitting layer, and a cathode. When foreign matter settles on the anode, the foreign matter may inhibit stable formation of the light emitting layer on the anode. Likewise, the foreign matter may inhibit stable formation of the cathode on the light emitting layer. In this case, when the cathode and the anode electrically contact each other, a short circuit may occur. The short circuit can inhibit the light emitting device from emitting light, which may render one or more pixels of the organic light emitting display device defective, introducing dark spots in the organic light emitting display device.

Through an aging process, dark spots can be removed from the organic light emitting display device by normalizing defective pixels. However, there is a problem that dark spots may reoccur in the normalized pixels.

The present disclosure has been made, at least in part, in view of the abovementioned problems. Particularly, some aspects of the present disclosure are to provide display devices with reduced occurrence of dark spots.

In accordance with one aspect of the present disclosure, a display device is provided, the display device including: a plurality of pixels each including a circuit area and a transmission area; each pixel including a plurality of sub-pixels disposed in the circuit area; a voltage line disposed in the circuit area and supplying a voltage; and a plurality of connection lines disposed in the circuit area and electrically connected to the voltage line, wherein each of the plurality of sub-pixels includes a first cathode and a second cathode spaced apart from each other, and wherein the voltage line supplies the voltage to the first cathode through any one of the plurality of connection lines, and supplies the voltage to the second cathode through the other ones of the plurality of connection lines.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate examples of the present disclosure and together with the description serve to explain the principle of the present disclosure. In the drawings:

FIG. 1 is a schematic block diagram of a display device according to an example of the present disclosure.

FIGS. 2A-2C are plan views of a display device according to a first example of the present disclosure.

FIG. 3 is a plan view of a display device according to a second example of the present disclosure.

FIG. 4 is a cross-sectional view taken along a line A-A′ of FIG. 2A.

FIGS. 5A-5G are cross-sectional views taken along line B-B′ of FIG. 2A.

FIG. 6 is a circuit diagram of a sub-pixel according to an example of the present disclosure.

FIG. 7 is a circuit diagram of a sub-pixel according to another example of the present disclosure.

FIG. 8 is a plan view of a display device according to a third example of the present disclosure.

FIG. 9 is a cross-sectional view taken along a line C-C′ of FIG. 8.

FIG. 10 is a plan view of a display device according to a fourth example of the present disclosure.

FIG. 11 is a plan view of a display device according to a fifth example of the present disclosure.

FIG. 12 is a plan view of a display device according to a sixth example of the present disclosure.

FIG. 13 is a plan view of a display device according to a seventh example of the present disclosure.

Throughout the drawings and the detailed description, unless stated otherwise, like reference numerals refer to like elements, features, and structures. The relative size and depiction of these elements may be exaggerated for clarity, illustration, and/or convenience.

### DETAILED DESCRIPTION

The advantages and features of the present disclosure and methods for accomplishing the same will be more clearly understood from the examples described below with reference to the accompanying drawings. The present disclosure may, however, be embodied in different forms and should not be construed as limited to the following examples set forth herein. Rather, the following examples are provided so that this disclosure will be thorough and complete and will fully convey the scope of the present disclosure to those of ordinary skill in the art.

A shape, a size, a ratio, an angle, and a number disclosed in the accompanying drawings for describing the following examples of the present disclosure are merely examples and, thus, the present disclosure is not limited to the following examples. Unless stated otherwise, like reference numerals refer to like elements throughout the specification. In the following description, when the detailed description of the relevant known function or configuration is determined to unnecessarily obscure an important point of the present disclosure, the detailed description will be omitted. In a case where ‘comprise’, ‘have’ and ‘include’ described in the present disclosure are used, another portion may be added unless ‘only-’ is used. The terms of a singular form may include plural forms unless referred to the contrary.

In interpreting components, even if there is no explicit description, it is interpreted to include the scope of error.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

In describing a temporal precedence relationship, for example, when the temporal precedence relationship is described as ‘˜after’, ‘˜next to’, ‘˜before’, etc., it may also include cases where it is not continuous unless ‘right away’ or ‘directly’ is used.

First, second, etc. are used to describe various components, but these components are not limited by these terms. These terms are used only to distinguish one component from another. Therefore, a first component mentioned below may be a second component within the technical idea of the present disclosure.

Features of various examples of the present disclosure may be partially or overall coupled to or combined with each other and may be variously inter-operated with each other and driven technically as those skilled in the art can sufficiently understand. The examples of the present disclosure may be carried out independently from each other or may be carried out together in a co-dependent relationship.

Hereinafter, examples of the present disclosure will be described in detail with reference to the accompanying drawings.

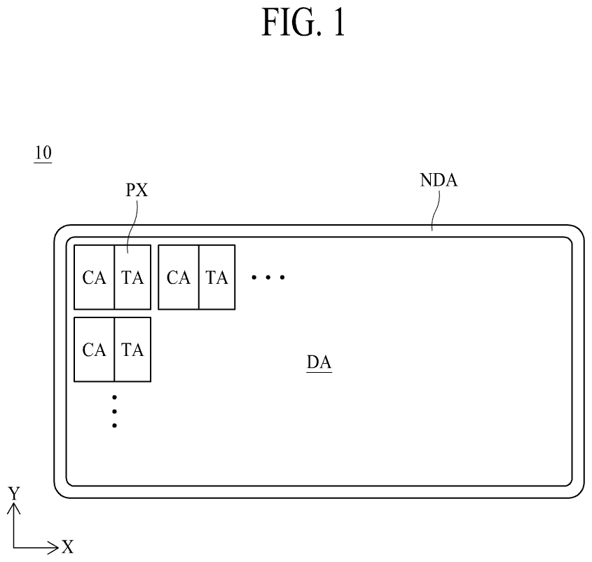

FIG. 1 is a schematic block diagram of a display device 10 according to an example of the present disclosure.

The display device 10 may include a display area DA and a non-display area NDA surrounding the display area DA. The display area DA may be an area in which an image may be displayed, and the non-display area NDA may be an area in which the image is not displayed.

A plurality of pixels PX may be disposed in the display area DA. The plurality of pixels PX may be arranged in a matrix structure arranged along a first direction X and a second direction Y. Each of the plurality of pixels PX may include a transmission area TA and a circuit area CA. The transmission area TA may be an area through which external light is transmitted. The circuit area CA is an area in which a light emitting device and a circuit for driving the light emitting device are disposed. The circuit area CA may implement the image. Accordingly, when the image is not implemented through the circuit area CA, a user may see an external image of the display device 10 through the transmission area TA.

In FIG. 1, a structure in which the transmissive area TA and the circuit area CA are disposed in the first direction X in one pixel PX is disclosed, but is not limited thereto.

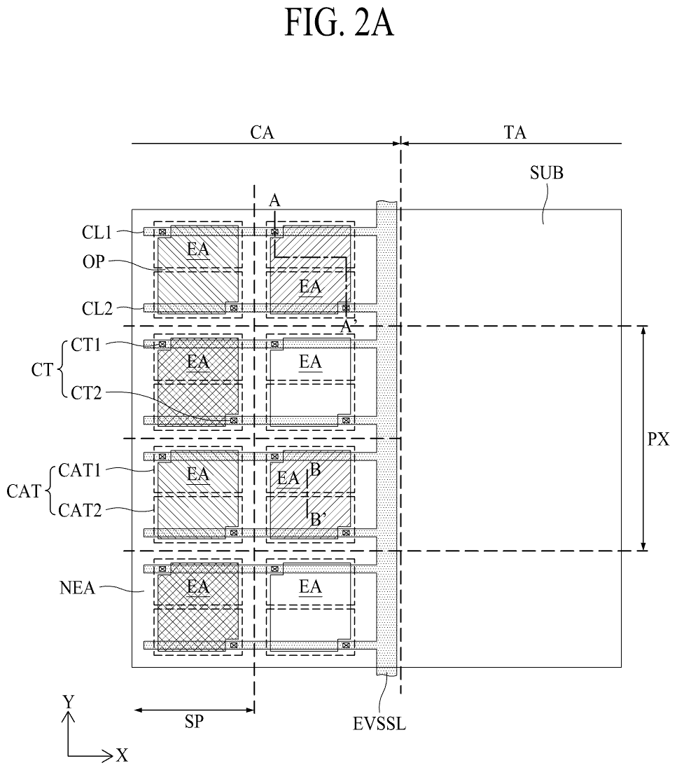

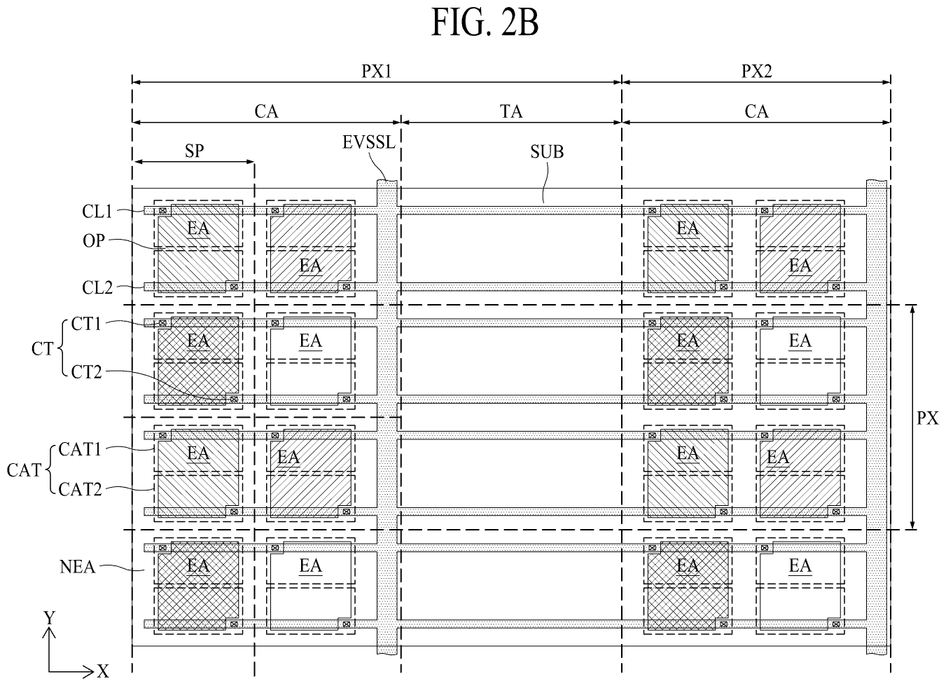

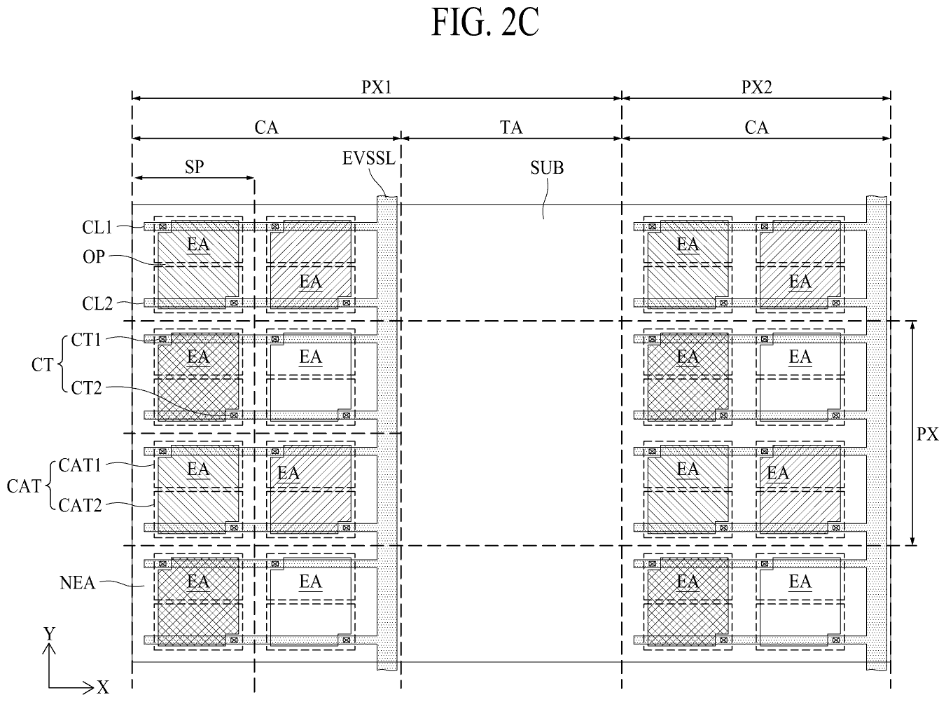

FIGS. 2A-2C are plan views of the display device 10 according to a first example of the present disclosure. Specifically, FIGS. 2A-2C illustrate a planar structure of the plurality of pixels PX.

Referring to FIG. 2A, the plurality of pixels PX may be disposed on a substrate SUB including the transmission area TA and the circuit area CA. A plurality of sub-pixels SP and a low potential voltage line EVSSL may be disposed in the circuit area CA. A light emitting device and a circuit for driving the light emitting device may not be disposed in the transmissive area TA, and only a transparent material layer may be disposed in the transmissive area TA.

Referring to FIG. 2A, one pixel PX may include a plurality of sub-pixels SP. The plurality of sub-pixels SP may be disposed in the circuit area CA. The plurality of sub-pixels SP may be disposed in a matrix structure arranged along the first and second directions X and Y, but are not limited thereto. FIG. 2A discloses that one pixel PX includes four sub-pixels SP, but is not limited thereto. In addition, each of the plurality of sub-pixels SP may emit any one of red, green, blue, or white light.

Each of the plurality of sub-pixels SP may include a light emitting area EA, a non-light emitting area NEA, and a contact area CT.

The light emitting area EA includes a light emitting device and may emit light. The light emitting area EA may have a concave portion. Referring to FIG. 2A, a structure in which an area of an upper end and an area of a lower end of the light emitting area EA have a concave shape is disclosed, but is not limited thereto.

The contact area CT may be disposed in the concave portion of the light emitting area EA. That is, the contact area CT may correspond to the concave shape of the light emitting area EA. A cathode CAT of the light emitting device and the low potential voltage line EVSSL may be electrically connected through the contact area CT.

The contact area CT may include a first contact area CT1 and a second contact area CT2. The first contact area CT1 and the second contact area CT2 may be disposed along the second direction Y. The first contact area CT1 may be disposed in an upper area of the sub-pixel SP, and the second contact area CT2 may be disposed in a lower area of the sub-pixel SP, but is not limited thereto. In addition, a contact hole may be disposed in each of the first contact area CT1 and the second contact area CT2.

The non-light emitting area NEA may surround the light emitting area EA and the contact area CT. Since the contact area CT is disposed in an area corresponding to the concave shape of the light emitting area EA, a partial area of the contact area CT may be adjacent to the light emitting area EA, and the remaining area of the contact area CT may be adjacent to the non-light emitting area NEA.

A light emitting device may be disposed in each of the plurality of sub-pixels SP. The light emitting device may include an anode, a light emitting layer, and a cathode CAT. FIGS. 2A-2C show only the cathode CAT.

The anode and the light emitting layer are disposed in the light emitting area EA and may be formed on an entire surface of the light emitting area EA. The anode and the light emitting layer may extend from the light emitting area EA and may also be disposed in a partial area of the non-light emitting area NEA. In addition, the anode and the light emitting layer may not be disposed in the contact area CT.

The cathode CAT may be disposed in the light emitting area EA. The cathode CAT may include a first cathode CAT1 and a second cathode CAT2. The first cathode CAT1 and the second cathode CAT2 may be disposed along the second direction Y. The first cathode CAT1 may be disposed in the upper area of the light emitting area EA, and the second cathode CAT2 may be disposed in the lower area of the light emitting area EA. In addition, the first cathode CAT1 and the second cathode CAT2 may be spaced apart from each other. The first cathode CAT1 and the second cathode CAT2 may be spaced apart from each other, and an area disposed between the first cathode CAT1 and the second cathode CAT2 may become an opening OP. That is, the first cathode CAT1 and the second cathode CAT2 may be electrically separated from each other. In addition, the opening OP may overlap the light emitting area EA. The opening OP may be parallel to the first direction X, but is not limited thereto.

Each of the first cathode CAT1 and the second cathode CAT2 may extend from the light emitting area EA and may also be disposed in a partial area of the non-light emitting area NEA. However, each of the first cathode CAT1 and the second cathode CAT2 is not disposed in the transmission area TA. In addition, the first cathode CAT1 may overlap the first contact area CT1, and the second cathode CAT1 may overlap the second contact area CT2. In addition, the first cathode CAT1 and the second cathode CAT2 may be formed to have the same size, but are not limited thereto.

The first cathode CAT1 and the second cathode CAT2 may include a transparent conductive material such as indium tin oxide (ITO) or indium zinc oxide (IZO). In addition, the first cathode CAT1 and the second cathode CAT2 may include the same material, but are not limited thereto.

A low potential voltage line EVSSL may be disposed in the circuit area CA adjacent to the transmission area TA. FIG. 2A illustrates that the low potential voltage line EVSSL is disposed adjacent to a right end of the circuit area CA, but is not limited thereto. For example, the low potential voltage line EVSSL may be disposed adjacent to a left end of the circuit area CA. In addition, the low potential voltage line EVSSL may be disposed in the non-light emitting area. The low potential voltage line EVSSL may be extend in the second direction Y.

A plurality of connection lines CL may be disposed in the circuit area CA. The plurality of connection lines CL may include a plurality of first connection lines CL1 and a plurality of second connection lines CL2. The plurality of first connection lines CL1 and the plurality of second connection lines CL2 may be spaced apart from each other. In addition, the plurality of first connection lines CL1 may be spaced apart from each other, and the plurality of second connection lines CL2 may be spaced apart from each other.

The plurality of first connection lines CL1 and the plurality of second connection lines CL2 may be disposed under the light emitting device 400. The plurality of first connection lines CL1 may overlap the first cathode CAT1, and the plurality of second connection lines CL2 may overlap the second cathode CAT2. One first connection line CL1 may overlap the plurality of first cathodes CAT1 disposed along the first direction X, and one second connection line CL2 may overlap a plurality of second cathodes CAT2 disposed along the first direction X.

The plurality of first connection lines CL1 and the plurality of second connection lines CL2 may be disposed in the contact area CT. The plurality of first connection lines CL1 may overlap the first contact area CT1, and the plurality of second connection lines CL2 may overlap the second contact area CT2. One first connection line CL1 may overlap a plurality of first contact areas CT1 disposed along the first direction X, and one second connection line CL2 may overlap a plurality of second contact areas CT2 disposed along the first direction X.

Since one sub-pixel SP includes at least one first contact area CT1 and at least one second contact area CT2, one sub-pixel SP may overlap one first connection line CL1 and one second connection line CL2. In addition, one first connection line CL1 may be connected to one sub-pixel SP and another sub-pixel adjacent to one sub-pixel SP. Likewise, one second connection line CL2 may be connected to one sub-pixel SP and another sub-pixel adjacent to one sub-pixel SP.

The plurality of first connection lines CL1 and the plurality of second connection lines CL2 may be electrically connected to the low potential voltage line EVSSL. Referring to FIG. 2B, the plurality of first connection lines CL1 and the plurality of second connection lines CL2 are formed to extend from one side of the low potential voltage line EVSSL, and may be parallel to the first direction X. That is, the plurality of first connection lines CL1 and the plurality of second connection lines CL2 may be integrally formed with the low potential voltage line EVSSL, but are not limited thereto. For example, the plurality of first connection lines CL1 and the plurality of second connection lines CL2 may be connected to the low potential voltage line EVSSL through a contact hole.

When one side of each of the plurality of first connection lines CL1 is connected to the low potential voltage line EVSSL, ends of the other sides of each of the plurality of first connection lines CL1 may be disposed in the circuit area CA. That is, ends of the other sides of each of the plurality of first connection lines CL1 extend to the adjacent sub-pixels SP, but may not extend to the transmission area TA. Likewise, when one side of each of the plurality of second connection lines CL2 is connected to the low potential voltage line EVSSL, ends of the other sides of each of the plurality of second connection lines CL2 may be disposed in the circuit area CA. That is, ends of the other sides of each of the plurality of second connection lines CL2 extend to the adjacent sub-pixels SP, but may not extend to the transmission area TA.

Meanwhile, referring to FIGS. 2B and 2C, a circuit area CA of a plurality of second pixels PX2 adjacent to the plurality of first pixels PX1 is further illustrated.

Referring to FIG. 2B, the plurality of first connection lines CL1 and the plurality of second connection lines CL2 may be commonly formed in the circuit area CA of the plurality of first pixels PX1 and the plurality of second pixels PX2. That is, the low potential voltage line EVSSL disposed in a plurality of first pixels PX1, the low potential voltage line EVSSL disposed in the plurality of second pixels PX2, the plurality of first connection lines CL1, and the plurality of second connection lines CL2 may have a mesh structure. In this case, the plurality of first connection lines CL1 and the plurality of second connection lines CL2 may also be disposed in the transmission area TA of the plurality of first pixels PX1. Accordingly, a problem that may occur is that the transmittance of the transmission area TA is lowered, and the reflectance of the transmission area TA is increased.

Accordingly, as shown in FIG. 2C, the plurality of first connection lines CL1 disposed in the plurality of first pixels PX1 and the plurality of first connection lines CL1 disposed in the plurality of second pixels PX2 may be separated, and it may be preferable that the plurality of first connection lines CL1 are not formed in the transmission area TA. Likewise, the plurality of second connection lines CL2 provided in the plurality of first pixels PX1 and the plurality of second connection lines CL2 provided in the plurality of second pixels PX2 may also be separated, and it may be preferable that the plurality of second connection lines CL2 are not formed in the transmission area TA.

The low potential voltage line EVSSL may supply a low potential voltage EVSS to the plurality of sub-pixels SP through the plurality of first connection lines CL1 and the plurality of second connection lines CL2. Specifically, the first connection line CL1 may be electrically connected to the first cathode CAT1 through a contact hole of the first contact area CT1. In addition, the second connection line CL2 may be electrically connected to the second cathode CAT2 through a contact hole of the second contact area CT2.

That is, one sub-pixel SP may include the first cathode CAT1 receiving the low potential voltage EVSS from the first connection line CL1 and the second cathode CAT2 receiving the low potential voltage EVSS from the second connection line CL2. Accordingly, even when any one of the first cathode CAT1 and the second cathode CAT2 is not normally driven, the sub-pixel SP may emit light through the other one of the first cathode CAT1 and the second cathode CAT2.

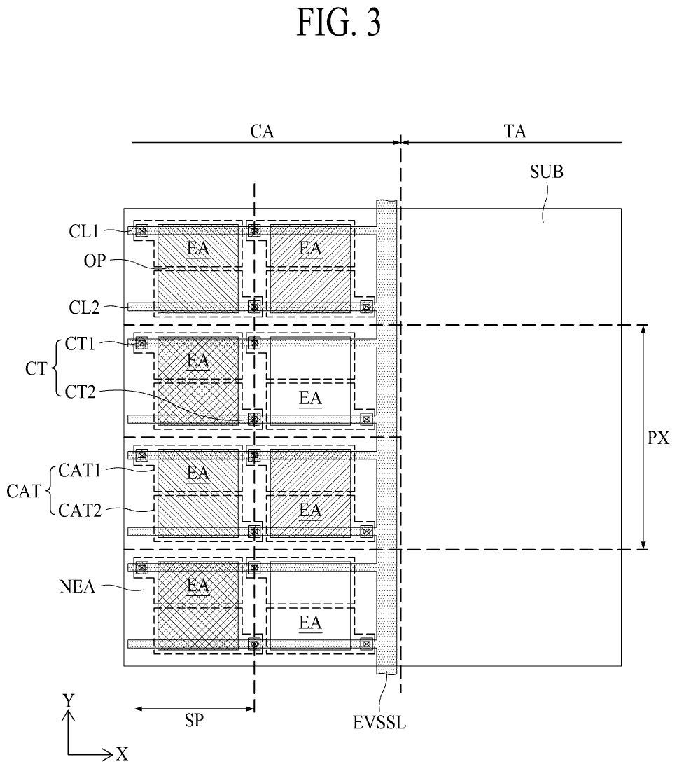

FIG. 3 is a plan view of the display device 10 according to a second example of the present disclosure.

Compared with FIGS. 2A-2C, except for the structures of the light emitting area EA and the contact area CT, FIG. 3 illustrates substantially the same structure as FIGS. 2A-2C. Accordingly, the same reference numerals are used for the same components as the display device 10 illustrated in FIGS. 2A-2C, and repeated descriptions thereof are omitted.

As described above, each of the plurality of sub-pixels SP may include the light emitting area EA, the non-light emitting area NEA, and the contact area CT. Compared with the light emitting area EA of FIGS. 2A-2C, the light emitting area EA of FIG. 3 may not have a concave shape. That is, compared with FIGS. 2A-2C, FIG. 3 may secure a wider light emitting area EA.

The contact area CT may include a first contact area CT1 and a second contact area CT2. The first contact area CT1 may be adjacent to one side of the light emitting area EA, and the second contact area CT2 may be adjacent to the other side of the light emitting area EA.

Each of the first cathode CAT1 and the second cathode CAT2 may extend from the light emitting area EA and may also be disposed in a partial area of the non-light emitting area NEA. However, each of the first cathode CAT1 and the second cathode CAT2 is not disposed in the transmission area TA. In addition, the first cathode CAT1 may overlap the first contact area CT1, and the second cathode CAT1 may overlap the second contact area CT2. That is, the first cathode CAT1 may have a shape in which a partial area of the first cathode CAT1 protrudes toward the first contact area CT1, and the second cathode CAT2 may have a shape in which a partial area the second cathode CAT2 protrudes toward the second contact area CT2.

As described in FIGS. 2A-2C, the first connection line CL1 may be electrically connected to the first cathode CAT1 through the contact hole of the first contact area CT1. In addition, the second connection line CL2 may be electrically connected to the second cathode CAT2 through the contact hole of the second contact area CT2.

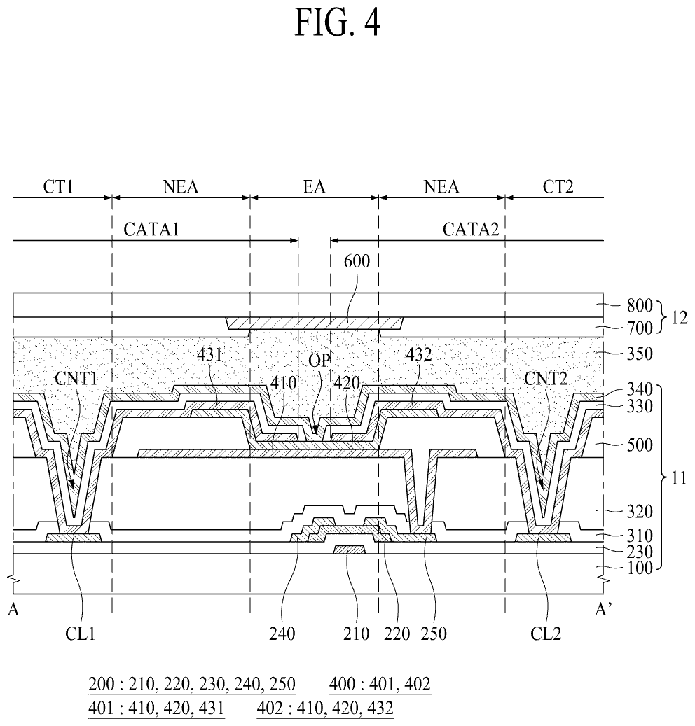

FIG. 4 is a cross-sectional view taken along a line A-A′ of FIG. 2A. Specifically, FIG. 4 illustrates a cross-sectional view of one sub-pixel SP.

Referring to FIG. 4, one sub-pixel SP according to an example of the present disclosure may include a first substrate 100, a thin film transistor 200, a passivation layer 310, a planarization layer 320, a capping layer 330, a protective layer 340, an encapsulation layer 350, a light emitting device 400, a bank 500, a color filter 600, a black matrix 700, and a second substrate 800.

In this case, the first substrate 100, the thin film transistor 200, the passivation layer 310, the planarization layer 320, the capping layer 330, and the protective layer 340 may be included in a circuit unit 11, and the color filter 600, the black matrix 700, and the second substrate 800 may be included in a filter unit 12. The circuit unit 11 and the filter unit 12 may be bonded together through the encapsulation layer 350.

The first substrate 100 may be made of glass or plastic, but is not limited thereto. The display device 10 according to an example of the present disclosure may be configured in a top emission scheme in which emitted light is emitted upward. Therefore, as a material of the first substrate 100, not only a transparent material but also an opaque material may be used.

The thin film transistor 200 may be disposed on the first substrate 100. The thin film transistor 200 may be disposed in the light emitting area EA or the non-light emitting area NEA. The thin film transistor 200 may include a gate electrode 210, a semiconductor layer 220, a gate insulating layer 230, a source electrode 240, and a drain electrode 250.

The gate electrode 210 of the thin film transistor 200 may be disposed on the first substrate 100. In addition, the semiconductor layer 220 may be disposed on the gate electrode 210. The semiconductor layer 220 may include a poly-silicon semiconductor or an oxide semiconductor. In addition, when the semiconductor layer 220 includes the oxide semiconductor, at least one oxide of indium-gallium-zinc-oxide (IGZO), indium-gallium-tin-oxide (IGO), and indium-gallium-oxide (IGO) may be included.

To insulate the gate electrode 210 and the semiconductor layer 220, the gate insulating layer 230 may be disposed between the gate electrode 210 and the semiconductor layer 220. The gate insulating layer 230 may be formed of a single layer of silicon nitride (SiNx) or silicon oxide (SiOx), or multiple layers thereof. In addition, FIG. 4 illustrates a bottom gate structure in which the semiconductor layer 220 is formed on the gate electrode 210, but is not limited thereto. For example, a top gate structure in which the gate electrode 210 is formed on the semiconductor layer 220 may be disclosed.

The source electrode 240 and the drain electrode 250 may be disposed on the semiconductor layer 220 while facing each other. In addition, a connection line CL may be disposed on the same layer as the source electrode 240 and the drain electrode 250. The source electrode 240 and the drain electrode 250 may be formed by the same process as the connection line CL. The first connection line CL1 may be disposed in the first contact area CT1, and the second connection line CL2 may be disposed in the second contact area CT2.

The passivation layer 310 may be disposed on the thin film transistor 200 and the connection line CL. The passivation layer 310 may include a contact hole exposing a portion of the drain electrode 250 and a portion of the connection line CL. In addition, the passivation layer 310 may be formed of an inorganic insulating material such as silicon oxide (SiOx), silicon nitride (SiNx), silicon oxynitride (SiOxNy), or the like.

The planarization layer 320 may be disposed on the passivation layer 310. The planarization layer 320 is disposed in the light emitting area EA, the non-light emitting area NEA, and the contact area CT, and upper portions of the thin film transistor 200 and the connection line CL may be planarized. In addition, the planarization layer 320 may be formed of an organic insulating material such as an acrylic resin, an epoxy resin, a phenolic resin, a polyamide resin, or a polyimide resin.

The light emitting device 400 may be disposed on the planarization layer 320. The light emitting device 400 may include a first light emitting device 401 and a second light emitting devices 402.

The first light emitting device 401 may include an anode 410, a light emitting layer 420, and a first cathode 431.

The anode 410 may be disposed on the planarization layer 320. The anode 410 may be disposed in the light emitting area EA and the non-light emitting area NEA. In addition, the anode 410 may be electrically connected to the drain electrode 250 of the thin film transistor 200 through contact holes disposed in the passivation layer 310 and the planarization layer 320.

The anode 410 may include a transparent conductive material such as indium tin oxide (ITO) or indium zinc oxide (IZO). Alternatively, the anode 410 may include a metal material such as aluminum (Al), silver (Ag), copper (Cu), molybdenum (Mo), titanium (Ti), tungsten (W), or chromium (Cr), or an alloy thereof. Further, the anode 410 is shown as a single layer, but may be a multiple layer.

The bank 500 may be disposed on the planarization layer 320 and the anode 410. The bank 500 may define the non-light emitting area NEA. That is, an area in which the bank 500 is not disposed may be the light emitting area EA or the contact area CT, and an area in which the bank 500 is disposed may be the non-light emitting area NEA.

The bank 500 may include an organic insulating material such as an acrylic resin, an epoxy resin, a phenolic resin, a polyamide resin, a polyimide resin, etc. Alternatively, the bank 500 may include an inorganic insulating material such as silicon oxide (SiOx), silicon nitride (SiNx), silicon oxynitride (SiOxNy), etc. In addition, the bank 500 may include a black dye to absorb light incident from the outside.

The light emitting layer 420 may be disposed on the anode 410. In addition, the light emitting layer 420 may be disposed on an upper surface of the bank 500. That is, the light emitting layer 420 may be disposed in the light emitting area EA and the non-light emitting area NEA.

The light emitting layer 420 may include a hole transporting layer, an organic light emitting layer, and an electron transporting layer. In this case, when a voltage is applied to the anode 410 and the first cathode 431, holes and electrons move to the organic light emitting layer through the hole transport layer and the electron transport layer, respectively, and holes and electrons may combine with each other to emit light in the organic light emitting layer.

The first cathode 431 may be disposed on the light emitting layer 420. Like the light emitting layer 420, the first cathode 431 may be disposed on the upper surface of the bank 500. In addition, the first cathode 431 may extend from the upper surface of the bank 500 and may also be disposed in the first contact area CT1. In this case, an area in which the first cathode 431 is disposed may be referred to as a first cathode area CATA1.

Since the display device 10 according to an example of the present disclosure is configured in a top emission method, the first cathode 431 may include a transparent conductive material such as an indium tin oxide (ITO) or an indium zinc oxide (IZO) to transmit light emitted from the light emitting layer 420 upward.

Like the first light emitting device 401, the second light emitting device 402 may include an anode 410 and a light emitting layer 420. The anode 410 of the first light emitting device 401 and the anode 410 of the second light emitting device 402 may be formed continuously. That is, the first light emitting device 401 and the second light emitting device 402 may share the anode 410. Alternatively, the anode 410 of the first light emitting device 401 may be separated from the anode 410 of the second light emitting device 402. In addition, the light emitting layer 420 of the first light emitting device 401 and the light emitting layer 420 of the second light emitting device 402 may be formed continuously. That is, the first light emitting device 401 and the second light emitting device 402 may share the light emitting layer 420.

Unlike the first light emitting device 401 including the first cathode 431, the second light emitting device 402 may include a second cathode 432. The first cathode 431 and the second cathode 432 may be spaced apart from each other on the light emitting layer 420 by the opening OP. Accordingly, the first cathode 431 and the second cathode 432 may be physically separated by the opening OP. In addition, the opening OP is disposed in an area overlapping the light emitting layer 420, and may be disposed in the light emitting area EA.

The second cathode 432 may be disposed on the light emitting layer 420. Like the light emitting layer 420, the second cathode 432 may be disposed on the upper surface of the bank 500. In addition, the second cathode 432 may extend from the upper surface of the bank 500 and may also be disposed in the second contact area CT2. In this case, the area in which the second cathode 432 is disposed may be referred to as a second cathode area CATA2.

Since the display device 10 according to an example of the present disclosure is configured in the top emission method, the second cathode 432 may include a transparent conductive material such as an indium tin oxide (ITO) or an indium zinc oxide (IZO) to transmit light emitted from the light emitting layer 420 upward. In addition, the first cathode 431 and the second cathode 432 may include the same material, but are not limited thereto.

A first contact hole CT1 may be disposed in the first contact area CT1. The first contact hole CT1 may pass through the passivation layer 310, the planarization layer 320, and the bank 500, and may expose a partial area of the first connection line CL1. The first cathode 431 may also be disposed inside the first contact hole CT1. Accordingly, the first cathode 431 may be electrically connected to the first connection line CL1 through the first contact hole CT1.

A second contact hole CT2 may be disposed in the second contact area CT2. The second contact hole CT2 may pass through the passivation layer 310, the planarization layer 320, and the bank 500, and may expose a partial area of the second connection line CL2. The second cathode 432 may also be disposed inside the second contact hole CT2. Accordingly, the second cathode 432 may be electrically connected to the second connection line CL2 through the second contact hole CT2.

Meanwhile, since the first light emitting device 401 and the second light emitting device 402 share the anode 410, the first light emitting device 401 and the second light emitting device 402 may be electrically connected to the drain electrode 250 of the same thin film transistor 200. In addition, the first cathode 431 of the first light emitting device 401 and the second cathode 432 of the second light emitting devices 402 may be spaced apart from each other by the opening OP. Accordingly, the anode 410 of the first light emitting device 401 and the anode 410 of the second emitting device 402 may be electrically connected, and the first cathode 431 of the first light emitting device 401 and second cathode 432 of the second light emitting device 402 may not be electrically connected.

The capping layer 330 may be disposed on the first cathode 431 and the second cathode 432, and may cover an entire surface of the first cathode 431 and the second cathode 432. That is, the capping layer 330 may be disposed in the light emitting area EA, the non-light emitting area NEA, and the contact area CT. In addition, the capping layer 330 may be spaced apart from the area overlapping the opening OP. That is, the capping layer 330 covering the first cathode 431 and the capping layer 330 covering the second cathode 432 may be spaced apart from each other. The capping layer 330 may be formed of an inorganic insulating material such as silicon oxide (SiOx), silicon nitride (SiNx), silicon oxynitride (SiOxNy), or the like.

The protective layer 340 may be disposed on the capping layer 330 and may be disposed in the light emitting area EA, the non-light emitting area NEA, and the contact area CT. The protective layer 340 may protect the first emitting device 401 and the second light emitting device 402. Particularly, the protective layer 340 may cover the light emitting layer 420 exposed by the first cathode 431, the second cathode 432 and the capping layer 330. In addition, the protective layer 340 may be formed of an inorganic insulating material such as silicon oxide (SiOx), silicon nitride (SiNx), silicon oxynitride (SiOxNy), or the like.

The color filter 600 and the black matrix 700 may be disposed under the second substrate 800. The color filter 600 may be disposed in the light emitting area EA. The color filter 600 may transmit light of a specific color. For example, when the sub-pixel SP shown in FIG. 4 is a red sub-pixel, the color filter 600 may transmit only red light. In addition, the black matrix 700 may be disposed in the non-light emitting area NEA and the contact area CT. The black matrix 700 may include a material that blocks light.

The encapsulation layer 350 may be disposed between the protective layer 340 and the color filter 600 and between the protective layer 340 and the black matrix 700. The encapsulation layer 350 may fill an inside of the first contact holes CNT1 and the second contact holes CNT2. In addition, the encapsulation layer 350 may include an organic insulating material such as an acrylic resin, an epoxy resin, a phenolic resin, a polyamide resin, and a polyimide resin.

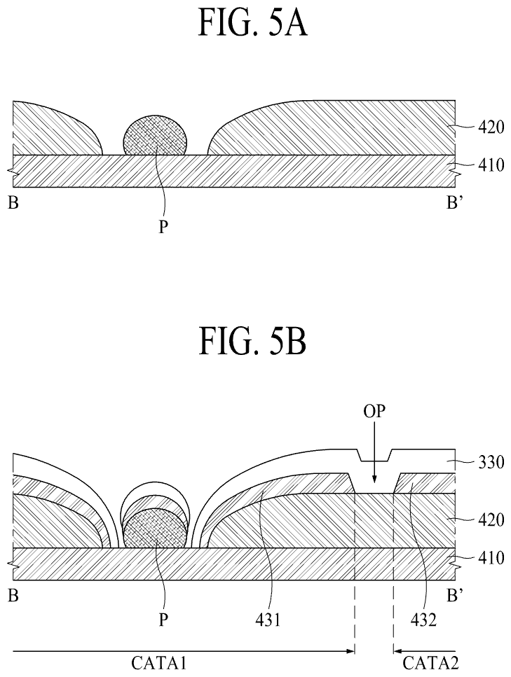

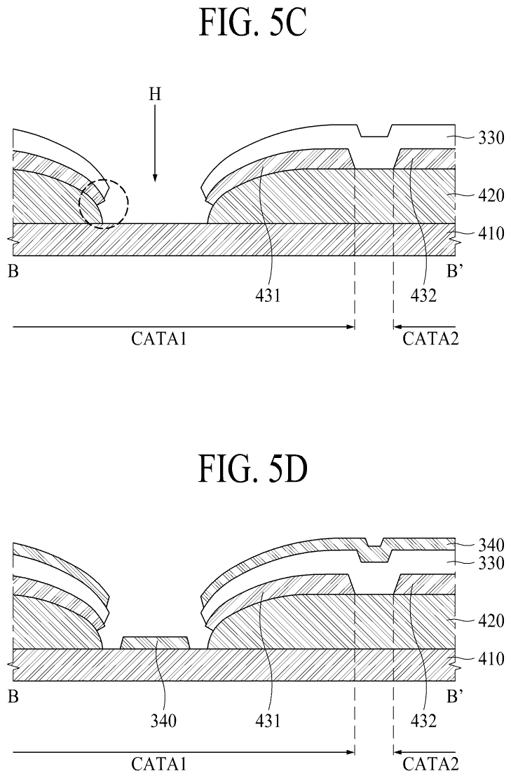

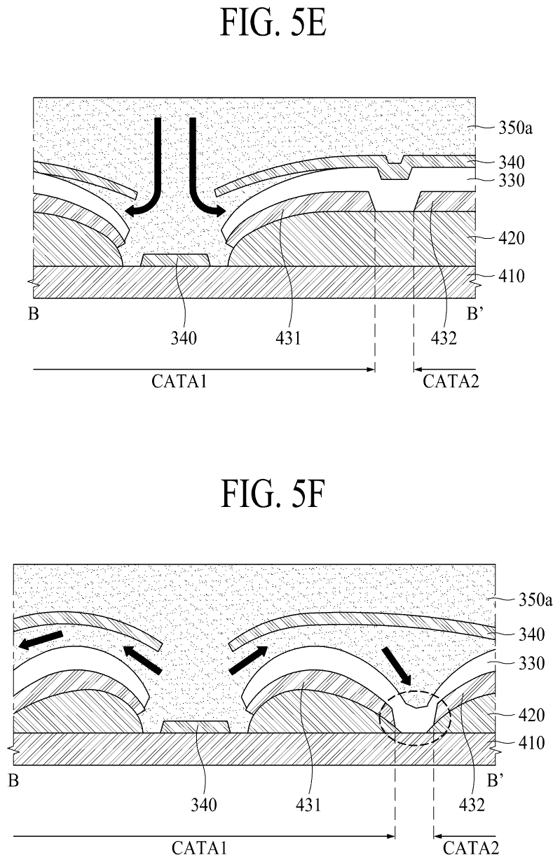

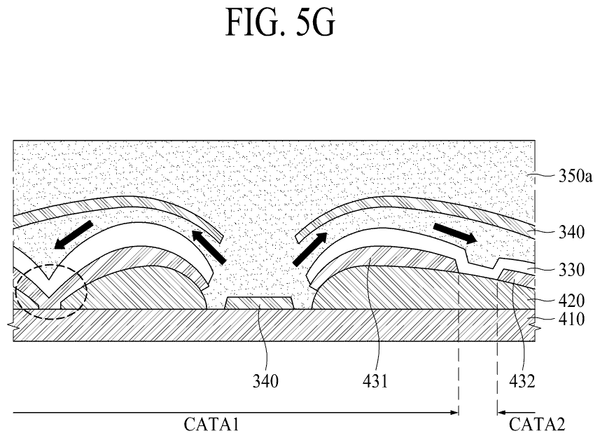

FIGS. 5A-5G are cross-sectional views taken along line B-B′ of FIG. 2A. Specifically, a case in which a foreign matter P is introduced in a process of forming a first light emitting device 401 and a second light emitting device 402 is illustrated.

Referring to FIG. 5A, a foreign matter P may be seated on an anode 410. Due to the foreign matter P, a light emitting layer 420 may not be formed on an entire surface of the anode 410. Specifically, the light emitting layer 420 may not be formed on the upper surface of the anode 410 on which the foreign matter P is seated and in a partial area of the anode 410 adjacent to the foreign matter P. That is, a partial area of the anode 410 may be exposed to an outside due to the foreign matter P.

Referring to FIG. 5B, a first cathode 431 and a second cathode 432 may be formed on the light emitting layer 420. The first cathode 431 and the second cathode 432 may be spaced apart from each other by an opening OP. In this case, an area in which the first cathode 431 is disposed may be a first cathode area CATA1, and an area in which the second cathode 432 is disposed may be a second cathode area CATA2.

Accordingly, a first light emitting device 401 including the anode 410, the light emitting layer 420, and the first cathode 431 may be formed. In addition, a second light emitting device 402 including the anode 410, the light emitting layer 420, and the second cathode 432 may be formed.

A capping layer 330 may be formed on the first cathode 431 and the second cathode 432. The capping layer 330 covers entire surfaces of the first cathode 431 and the second cathode 432, and may also be disposed in the opening OP.

FIG. 5B shows a case in which the foreign matter P is seated in the first cathode area CATA1. Since the first cathode 431 is deposited along a shape of the light emitting layer 420, a partial area of the first cathode 431 may be spaced apart by the foreign matter P. In this case, a partial area of the anode 410 exposed by the foreign matter P may be in contact with the first cathode 431. Accordingly, a short circuit may occur between the anode 410 and the first cathode 431, and the sub-pixel SP may not be driven normally.

To solve this problem, an aging process may be performed. Specifically, an aging signal may be applied to the first light emitting device 401. The aging signal may be a power source, or a signal applied to the first light emitting device 401 so that a predetermined current flows through the first light emitting device 401. When the aging signal is applied to the first light emitting device 401, the current may be concentrated in a region where the anode 410 and the first cathode 431 are in contact with each other. Accordingly, heat may be generated in the region where the anode 410 and the first cathode 431 are in contact with each other by Joule heating. By the generated heat, ends of the capping layer 330 and the first cathode 431 are melted, and the first cathode 431 and the anode 410 may be separated from each other.

That is, as illustrated in FIG. 5C, the first cathode 431 and the anode 410 may be separated from each other. The foreign matter P may be removed. In addition, a region from which the foreign matter P is removed may be a groove H. A partial area of the anode 410 is exposed, and molten ends of the first cathode 431 and the capping layer 330 may be disposed in the groove H.

Referring to FIG. 5D, a protective layer 340 may be formed on the capping layer 330. The protective layer 340 may be formed along a shape of the capping layer 330. That is, a partial area of the capping layer 330 may be spaced apart from each other by the groove H. In addition, a thickness of the protective layer 340 may decrease as it approaches the groove H.

As described above, in the display device 10 of the present disclosure, the circuit unit 11 and the filter unit 12 may be bonded through the encapsulation layer 350. In a process of bonding the circuit unit 11 and the filter unit 12, as shown in FIG. 5E, a bonding material 350a constituting the encapsulation layer 350 may apply pressure to the protective layer 340.

Since the capping layer 330 and the protective layer 340 are made of inorganic insulating materials such as silicon oxide (SiOx), silicon nitride (SiNx), silicon oxynitride (SiOxNy), and the like, adhesion between the capping layer 330 and the protective layer 340 is not high. Accordingly, a partial area of the protective layer 340 may be spaced apart from the capping layer 330 by the pressure applied to the protective layer 340 by the bonding material 350a. Specifically, an edge area of the protective layer 340 adjacent to the groove H may be spaced apart from the capping layer 330. The bonding material 350a may be introduced into a region between the capping layer 330 and the protective layer 340 which are spaced apart from each other.

Since the bonding material 350a has fluidity, as shown in FIGS. 5F and 5G, the bonding material 350a may be introduced between the capping layer 330 and the protective layer 340. Once introduced, the bonding material 350a may apply pressure to the capping layer 330. Accordingly, the first light emitting device 401 and the second light emitting device 402 may receive pressure.

Referring to FIG. 5F, a case where the bonding material 350a applies pressure to the opening OP is illustrated. The light emitting layer 420 made of an organic material may be bent and a thickness of the light emitting layer 420 may be reduced by the pressure applied to the opening OP. The thickness of the light emitting layer 420 decreases, and a partial area of the light emitting layer 420 may be spaced apart in an area overlapping the opening OP. In this case, since the first cathode 431 and the second cathode 432 are not disposed in the opening OP, the anode 410 may be in contact with the capping layer 330 in an area where the light emitting layer 420 is spaced apart from each other. Since the capping layer 330 is made of an inorganic insulating material, even if the capping layer 330 contacts the anode 410, the capping layer 330 may not affect a driving of the first light emitting device 401 and the second light emitting 402. Accordingly, the first light emitting device 401 and the second light emitting 402 may be driven normally.

In addition, referring to FIG. 5G, a case where the bonding material 350a applies pressure to the first cathode 431 is illustrated. Due to the pressure applied to the first cathode 431, the light emitting layer 420 made of an organic material may be bent and the thickness of the light emitting layer 420 may be reduced. The thickness of the light emitting layer 420 decreases, and a partial area of the light emitting layer 420 may be spaced apart from each other. Accordingly, the first cathode 431 may be in contact with the anode 410 in an area where the light emitting layer 420 is spaced apart from each other. That is, a short circuit may occur again between the first cathode 431 and the anode 410. Accordingly, the first light emitting device 401 may not be driven normally.

However, since the second light emitting device 402 is normally formed, the second light emitting device 402 may be driven normally. Accordingly, since the sub-pixel SP may emit light through the second light emitting device 402, the sub-pixel SP may normally emit light even when the first light emitting device 401 is not driven.

In conclusion, the present disclosure may normally operate the sub-pixel SP even if a short circuit occurs again in the sub-pixel SP after removing foreign matter and short circuits through the aging process. Specifically, even if any one of the first light emitting device 401 and the second light emitting device 402 is not driven, the sub-pixel SP may emit light through the other light emitting device. Accordingly, an additional repair process may be omitted. In addition, a possibility of occurrence of dark spots due to short circuits may be reduced, thereby improving stability of a display device.

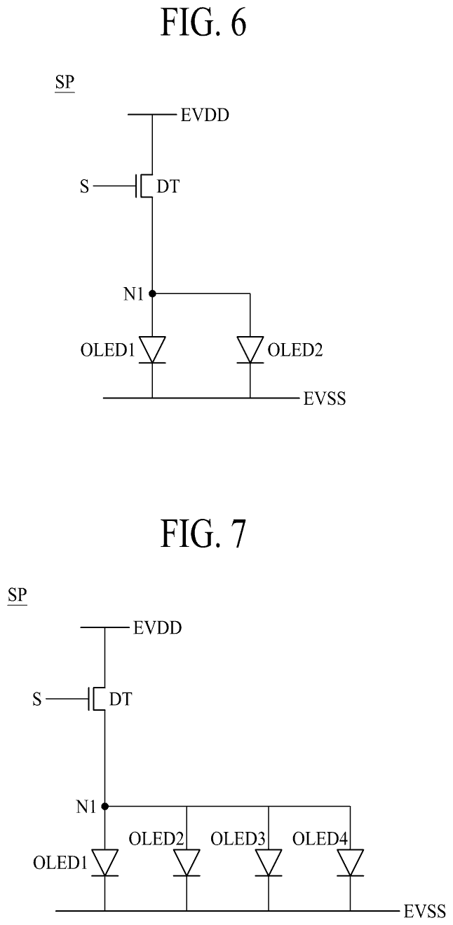

FIG. 6 is a circuit diagram of a sub-pixel SP according to an example of the present disclosure. Specifically, FIG. 6 illustrates a circuit diagram of the sub-pixel SP according to the plan view of FIGS. 2A-2C and 3.

The sub-pixel SP may include a driving transistor DT, a first light emitting device OLED1, and a second light emitting device OLED2. In addition, a switching transistor and a capacitor may be further included.

The driving transistor DT of the sub-pixel SP includes a gate electrode, a source electrode, and a drain electrode. Since the source electrode and the drain electrode are not fixed and may be changed according to a voltage and current direction applied to the gate electrode, one of the source electrode and the drain electrode may be expressed as a first electrode, and the other one of the source electrode and the drain electrode may be expressed as a second electrode.

The first electrode of the driving transistor DT is supplied with a high potential voltage EVDD, and the second electrode may be connected to the first light emitting device OLED1 and the second light emitting device OLED2. Although not shown in FIG. 6, the driving transistor DT may control a light emission intensity of the first light emitting device OLED1 and the second light emitting device OLED2 by controlling a driving current according to a driving voltage of the capacitor.

The first light emitting device OLED1 may include an anode connected to the driving transistor DT and a first cathode receiving a low potential voltage EVSS. The second light emitting device OLED2 may include an anode connected to the driving transistor DT and a second cathode receiving the low potential voltage EVSS. That is, the first light emitting device OLED1 and the second light emitting device OLED2 may be controlled by the same driving transistor DT.

The anode of the first light emitting device OLED1 and the anode of the second light emitting device OLED2 may be connected to the driving transistor DT through a first node N1. On the other hand, the first cathode of the first light emitting device OLED1 and the second cathode of the second light emitting device OLED2 may be connected to the low potential voltage EVSS, respectively. Accordingly, even if any one of the first light emitting device OLED1 and the second light emitting device OLED2 is not normally supplied with the low potential voltage EVSS, the other light emitting device may be normally supplied with the low potential voltage EVSS. Accordingly, the sub-pixel SP may stably emit light.

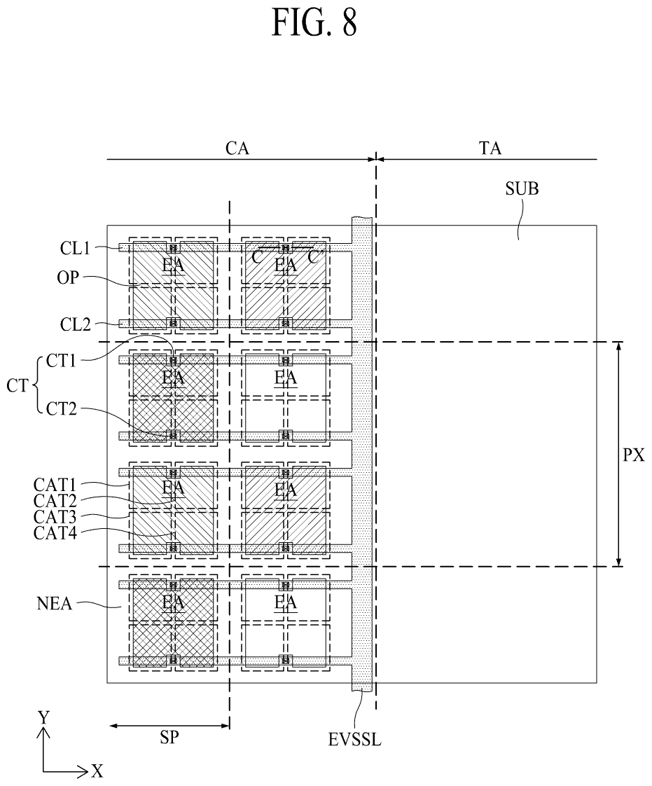

FIG. 7 is a circuit diagram of a sub-pixel SP according to another example of the present disclosure.

Compared with the sub-pixel SP of FIG. 6, the sub-pixel SP of FIG. 7 may further include a third light emitting device OLED3 and a fourth the second light emitting device OLED4.

The anode of the first to fourth light emitting devices OLED1 to OLED4 may be connected to the driving transistor DT through a first node N1. On the other hand, the first cathode of the first light emitting device OLED1, the second cathode of the second light emitting device OLED2, a third cathode of the third light emitting device OLED3, and a fourth cathode of the fourth light emitting device OLED4 may be connected to the low potential voltage EVSS, respectively. Accordingly, even if at least one of the first to fourth light emitting devices OLED1 to OLED4 is not normally supplied with the low potential voltage EVSS, the remaining light emitting devices may be normally supplied with the low potential voltage EVSS

Accordingly, compared to the sub-pixel SP of FIG. 6, the sub-pixel SP of FIG. 7 may further stably emit light.

FIG. 8 is a plan view of the display device 10 according to a third example of the present disclosure. In detail, FIG. 8 illustrates a plan view of the sub-pixel SP according to the circuit diagram of FIG. 7.

Compared with FIGS. 2A-2C, except for the structures of the light emitting area EA and the contact area CT, FIG. 8 illustrates substantially the same structure as FIGS. 2A-2C. Accordingly, the same reference numerals are used for the same components as the display device 10 illustrated in FIGS. 2A-2C, and repeated descriptions thereof are omitted.

Each of the plurality of sub-pixels SP may include a light emitting area EA, a non-light emitting area NEA, and a contact area CT.

The light emitting area EA includes a light emitting device and may emit light. The light emitting area EA may have a concave portion. Referring to FIG. 8, a structure in which an upper central area and a lower central area of the light emitting area EA have a concave shape is disclosed, but is not limited thereto.

The contact area CT may be disposed in the concave portion of the light emitting area EA. That is, the contact area CT may be disposed to correspond to the concave shape of the light emitting area EA. A cathode CAT of the light emitting device and a low potential voltage line EVSSL may be electrically connected to each other through the contact area CT.

The contact area CT may include a first contact area CT1 and a second contact areas CT2. The first contact area CT1 and the second contact areas CT2 may be disposed along the second direction Y. The first contact area CT1 may be disposed in an upper area of the sub-pixel SP, and the second contact area CT2 may be disposed in a lower area of the sub-pixel SP, but is not limited thereto. In addition, a contact hole may be disposed in each of the first contact area CT1 and the second contact areas CT2.

A light emitting device may be disposed in each of the plurality of sub-pixels SP. The light emitting device may include an anode, a light emitting layer, and a cathode CAT. FIG. 8 shows only the cathode CAT.

The anode and the light emitting layer are disposed in the light emitting area EA and may be formed on an entire surface of the light emitting area EA. The anode and the light emitting layer may extend from the light emitting area EA and may also be disposed in a partial area of the non-light emitting area NEA. In addition, the anode and the light emitting layer may not be disposed in the contact area CT. That is, the anode and the light emitting layer may not be disposed in the concave portion of the light emitting area EA. In addition, the anode may have a concave shape so as to correspond to the concave portion of the light emitting area EA.

The cathode CAT may be disposed in the light emitting area EA. The cathode electrode CAT may include a first cathode CAT1, a second cathode CAT2, a third cathode CAT3 and a fourth cathode CTA4. The first to fourth cathodes CAT1 to CAT4 may be arranged in a matrix structure. Specifically, in one light emitting area EA, the first cathode CAT1 and the second cathode CAT2 may be disposed in an upper area of the light emitting area EA, and the third cathode CAT3 and the fourth cathode CAT4 may be disposed in a lower area of the light emitting area EA. In addition, in one light emitting area EA, the first cathode CAT1 and the third cathode CAT3 may be disposed in a left area of the light emitting area EA, and the second cathode CAT2 and the fourth cathode CAT4 may be disposed in a right area of the light emitting area EA.

The first to fourth cathode electrodes CAT1 to CAT4 may be spaced apart from each other by an opening OP. That is, the first to fourth cathode electrodes CAT1 to CAT4 may be electrically separated from each other. In addition, the opening OP may overlap the light emitting area EA. The opening OP may be formed in a shape in which a first opening parallel to the first direction X and a second opening parallel to the second direction Y intersect, but the present disclosure is not limited thereto.

Each of the first to fourth cathodes CAT1 to CAT4 may extend from the light emitting area EA and may also be disposed in a partial area of the non-light emitting area NEA. In addition, the first cathode CAT1 and the second cathode CAT2 may overlap the first contact area CT1, and the third cathode CAT3 and the fourth cathode CAT4 may overlap the second contact area CT2. In addition, the first to fourth cathode electrodes CAT1 to CAT4 may be formed to have the same area, but are not limited thereto.

The first to fourth cathodes CAT1 to CAT4 may include a transparent conductive material such as indium tin oxide (ITO) or indium zinc oxide (IZO). In addition, the first to fourth cathodes CAT1 to CAT4 may include the same material, but are not limited thereto.

A plurality of first connection lines CL1 and a plurality of second connection lines CL2 may be disposed under the light emitting device. The plurality of first connection lines CL1 may overlap the first cathode CAT1 and the second cathode CAT2, and the plurality of second connection lines CL2 may overlap the third cathode CAT3 and the fourth cathode CAT4. One first connection line CL1 may overlap a plurality of first cathodes CAT1 and a plurality of second cathodes CAT2 disposed along the first direction X, and one second connection line CL2 may overlap a plurality of third cathodes CAT3 and a plurality of fourth cathodes CAT4 disposed along the first direction X.

The plurality of first connection lines CL1 and the plurality of second connection lines CL2 may be disposed in the contact area CT. The plurality of first connection lines CL1 may overlap the first contact area CT1, and the plurality of second connection lines CL2 may overlap the second contact area CT2. One first connection line CL1 may overlap a plurality of first contact areas CT1 disposed along the first direction X, and one second connection line CL2 may overlap a plurality of second contact areas CT2 disposed along the first direction X.

That is, one sub-pixel SP may overlap one first connection line CL1 and one second connection line CL2.

The low potential voltage line EVSSL may supply a low potential voltage EVSS to the plurality of sub-pixels SP through the plurality of first connection lines CL1 and the plurality of second connection lines CL2. Specifically, the first connection line CL1 may be electrically connected to the first cathode CAT1 and the second cathode CAT2 through a contact hole of the first contact area CT1. The second connection line CL2 may be electrically connected to the third cathode CAT3 and the fourth cathode CAT4 through a contact hole of the second contact area CT2.

That is, one sub-pixel SP may include the first cathode CAT1 and the second cathode CAT2 receiving the low potential voltage EVSS from the first connection line CL1, and the third cathode CAT3 and the fourth cathode CAT4 receiving the low potential voltage EVSS from the second connection line CL2. Accordingly, even when at least one cathode among the first to fourth cathodes CAT1 to CAT4 is not normally driven, the sub-pixel SP may emit light through the remaining cathodes.

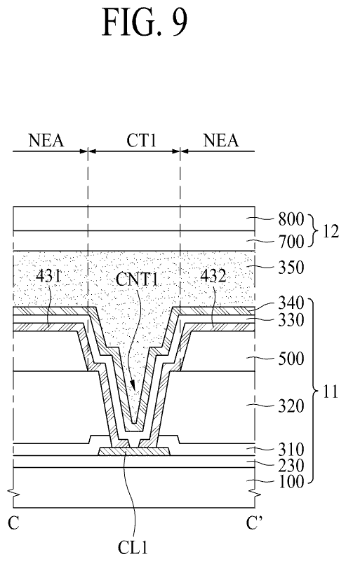

FIG. 9 is a cross-sectional view taken along a line C-C′ of FIG. 8. Specifically, the first contact area CT1 between the first cathode 431 and the second cathode 432 is illustrated.

Compared with FIG. 4, except for the structures of the first cathode 431 and the second cathode 432, FIG. 9 illustrates substantially the same structure as FIG. 4. Accordingly, the same reference numerals are used for the same components as the display device illustrated in FIG. 4, and repeated descriptions are omitted.

As described above, the first cathode CAT1 and the second cathode CAT2 may share the contact hole of the first contact area CT1, and the third cathode CAT3 and the fourth cathode CAT4 may share the contact hole of the second contact area CT2.

Referring to FIG. 9, a first contact hole CNT1 may be disposed in the first contact area CT1. The first contact hole CT1 may pass through the passivation layer 310, the planarization layer 320, and the bank 500, and may expose a partial area of the first connection line CL1. The first cathode 431 and the second cathode 432 may be disposed in the first contact hole CT1. Accordingly, the first cathode 431 and the second cathode 432 may be electrically connected to the first connection line CL1 through the first contact hole CT1.

The first cathode 431 and the second cathode 432 may be spaced apart from each other inside the first contact hole CNT1. The capping layer 330 may be disposed on the first cathode 431 and the second cathode 432, and may cover entire surfaces of the first cathode 431 and the second cathode 432. In this case, the capping layer 330 may also be disposed in a region separated between the first cathode 431 and the second cathode 432. Accordingly, the capping layer 330 may cover an exposed area of the first connection line CL1, and may stably insulate the first cathode 431 and the second cathode 432.

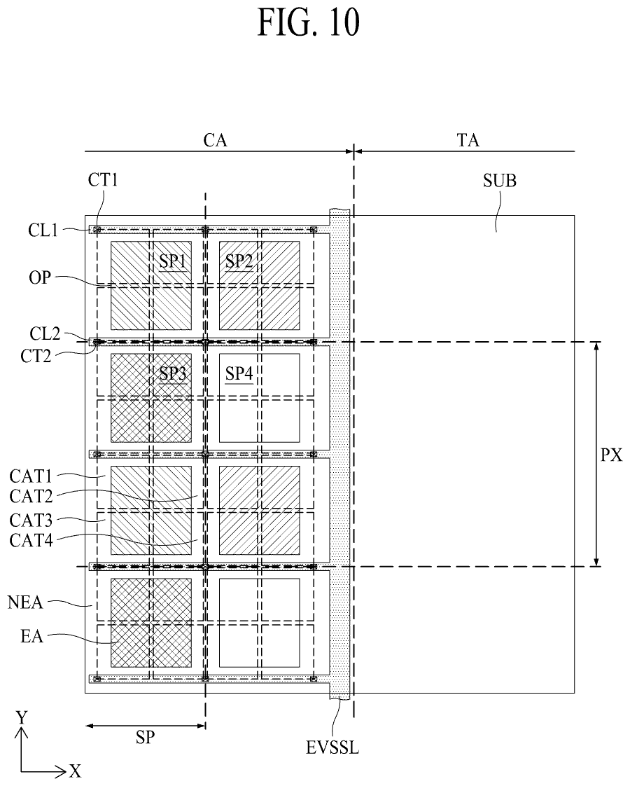

FIG. 10 is a plan view of the display device 10 according to a fourth example of the present disclosure.

Compared with FIG. 8, except for the structures of the light emitting area EA, the contact area CA, and the connection line CL, FIG. 10 illustrates substantially the same structure as FIG. 8. Accordingly, the same reference numerals are used for the same components as the display device 10 illustrated in FIG. 8, and repeated descriptions thereof are omitted.

Each of the plurality of pixels PX may include a first sub-pixel SP1, a second sub-pixel SP2, a third sub-pixel SP3 and a fourth sub-pixel SP4. The first to fourth sub-pixels SP1 to SP4 may be arranged in a matrix structure. Specifically, the first sub-pixel SP1 and the second sub-pixel SP2 may be disposed in an upper area of the pixel PX, and the third sub-pixel SP3 and a fourth sub-pixel SP4 may be disposed in a lower area of the pixel PX. In addition, the first sub-pixel SP1 and third sub-pixel SP3 may be disposed in a left area of the pixel PX, and the second sub-pixel SP2 and fourth sub-pixel SP4 may be disposed in a right area of the pixel PX.

As described above, each of the plurality of sub-pixels SP may include the light emitting area EA, the non-light emitting area NEA, and the contact area CT. Compared with the light emitting area EA of FIG. 8, the light emitting area EA of FIG. 10 may not have a concave shape. That is, compared with FIG. 8, FIG. 10 may secure a wider light emitting area EA.

The contact area CT may include a plurality of first contact areas CT1 and a plurality of second contact areas CT2.

The plurality of first contact areas CT1 may be disposed above the first sub-pixel SP1 and the second sub-pixel SP2. That is, the plurality of first contact areas CT1 may be disposed at an edge of the pixel PX. In addition, the plurality of first contact areas CT1 may be disposed at positions overlapping a straight line parallel to the first direction X while passing through a boundary of the sub-pixels SP adjacent to each other.

The plurality of second contact area CT2 may be disposed above the third sub-pixel SP3 and the fourth subpixels SP4. That is, the plurality of second contact areas CT2 may be disposed along a straight line that passes through a center of the pixel PX and is parallel to the first direction X. In addition, the plurality of second contact areas CT2 may be disposed at positions overlapping a straight line parallel to the first direction X while passing through the boundary of the subpixels SP adjacent to each other.

That is, the plurality of first contact areas CT1 and the plurality of second contact areas CT2 may be disposed at points adjacent to four sub-pixels SP.

In addition, the contact area CT may be disposed at an edge of the sub-pixel SP adjacent to the low potential voltage line EVSSL. For example, the contact area CT may be disposed at an edge of the second sub-pixel SP2 adjacent to the low potential voltage line EVSSL.

A contact hole may be disposed in each of the plurality of first contact area CT1 and the plurality of second contact areas CT2. The cathode CAT of the light emitting device and the low potential voltage line EVSSL may be electrically connected to each other through the contact area CT.

A cathode CAT may be disposed in the light emitting area EA. The cathode CAT may include a first cathode CAT1, a second cathode CAT2, a third cathode CAT3 and a fourth cathode CAT4. The first to fourth cathodes CAT1 to CAT4 may be arranged in a matrix structure. Specifically, the first cathode CAT1 and the second cathode CAT2 may be disposed in an upper area of the light emitting area EA, and the third cathode CAT3 and the fourth cathode CAT4 may be disposed in a lower area of the light emitting area EA. In addition, the first cathode CAT1 and the third cathode CAT3 may be disposed in a left area of the light emitting area EA, and the second cathode CAT2 and the fourth cathode CAT4 may be disposed in a right area of the light emitting area EA.

The first to fourth cathodes CAT1 to CAT4 may be spaced apart from each other by an opening OP. That is, the first to fourth cathodes CAT1 to CAT4 may be electrically separated from each other. In addition, the opening OP may overlap the light emitting area EA. The opening OP may be formed in a shape in which a first opening parallel to the first direction X and a second opening parallel to the second direction Y intersect, but is not limited thereto.

Each of the first to fourth cathodes CAT1 to CAT4 may extend from the light emitting area EA and may also be disposed in a partial area of the non-light emitting area NEA. Each of the first to fourth cathodes CAT1 to CAT4 may overlap the contact area CT. In addition, the first to fourth cathodes CAT1 to CAT4 may be formed to have the same area, but are not limited thereto.

The first to fourth cathodes CAT1 to CAT4 may include a transparent conductive material such as indium tin oxide (ITO) or indium zinc oxide (IZO). In addition, the first to fourth cathodes CAT1 to CAT4 may include the same material, but are not limited thereto.

The connection line CL may include a plurality of first connection lines CL1 and a plurality of second connection lines CL2. The plurality of first connection lines CL1 and the plurality of second connection lines CL2 may overlap the first to fourth cathodes CAT1 to CAT4. In addition, the one first connection line CL1 may overlap a plurality of first cathodes CAT1, a plurality of second cathodes CAT2, a plurality of third cathodes CAT3, and a plurality of fourth cathodes CAT4. In addition, one second connection line CL2 may overlap a plurality of first cathodes CAT1, a plurality of second cathodes CAT2, a plurality of third cathodes CAT3, and a plurality of fourth cathodes CAT4.

The plurality of first connection lines CL1 may be disposed in the first contact area CT1, and the plurality of second connection lines CL2 may be disposed in the second contact area CT2. One first connection line CL1 may overlap the plurality of first contact areas CT1 disposed along the first direction X, and one second connection line CL2 may overlap the plurality of second contact areas CT2 disposed along the first direction X.

In any one sub-pixel SP, the first cathode CAT1 and the second cathode CAT2 may overlap the same connection line CL, and the third cathode CAT3 and the fourth cathode CAT4 may overlap the same connection line CL. For example, in the first sub-pixel SP1, the first cathode CAT1 and the second cathode CAT2 may overlap the first connection line CL1, and the third cathode CAT3 and the fourth cathode CAT4 may overlap the second connection line CL2. That is, any one sub-pixel SP may overlap at least two connection lines CL.

The low potential voltage line EVSSL may supply the low potential voltage EVSS to the plurality of sub-pixels SP through the plurality of first connection lines CL1 and the plurality of second connection lines CL2. In detail, the connection line CL may be electrically connected to the plurality of cathodes CAT through a contact hole in any one contact area CT.

For example, the first connection line CL1 may be electrically connected to the second cathode CAT2 of the first sub-pixel SP1, the first cathode CAT1 of the second sub-pixel SP2, the fourth cathode CAT4 of the third sub-pixel SP3, and the third cathode CAT3 of the fourth sub-pixel SP4 through the contact hole of the first contact area CT1. Alternatively, the second connection line CL2 may be electrically connected to the fourth cathode CAT4 of the first sub-pixel SP1, the third cathode CAT3 of the second sub-pixel SP2, the second cathode CAT2 of the third sub-pixel SP3, and the first cathode CAT1 of the fourth sub-pixel SP4. Alternatively, the second connection line CL2 may be electrically connected to the fourth cathode CAT4 of the second sub-pixel SP2 and the second cathode CAT2 of the fourth sub-pixel SP4 through the contact hole of the second contact area CT2.

That is, one contact area CT may be electrically connected to the cathodes of different sub-pixels SP. In addition, the cathodes of different sub-pixels SP may receive the low potential voltage EVSS from the same connection line CL.

Accordingly, even when at least one cathode of the first to fourth cathodes CAT1 to CAT4 is not normally driven, the sub-pixel SP may emit light through the remaining cathodes.

An example of FIG. 8 discloses that each of the plurality of contact area CT supplies the low potential voltage EVSS to the two cathode electrodes CAT. On the other hand, an example of FIG. 10 discloses that some of the plurality of contact areas CT supplies the low potential voltage EVSS to the two cathodes CAT and the remaining contact areas CT supplies the low potential voltage EVSS to the four cathodes CAT. Accordingly, the number of contact areas CT may be reduced, thereby minimizing a loss of an aperture ratio.

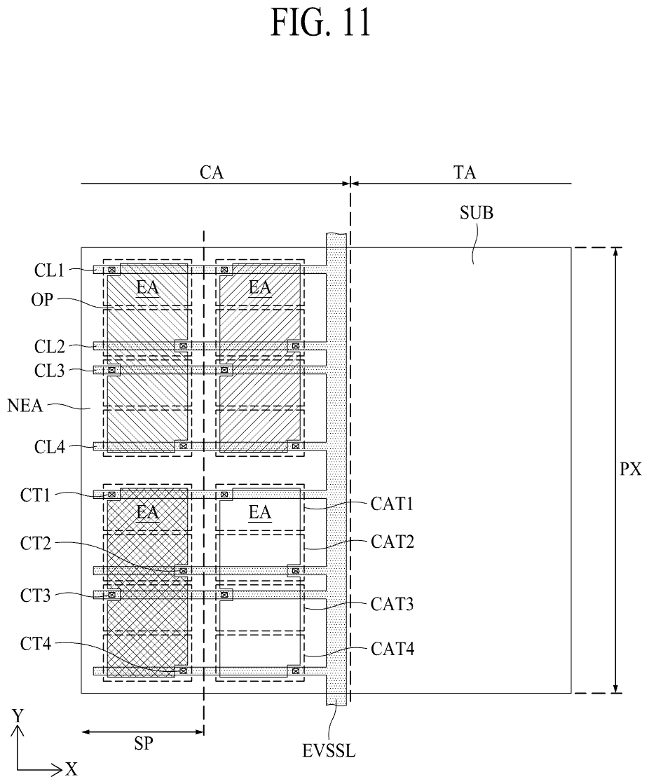

FIG. 11 is a plan view of the display device 10 according to a fifth example of the present disclosure.

As described above, each of the plurality of sub-pixels SP may include the light emitting area EA, the non-light emitting area NEA, and the contact area CT.

The light emitting area EA includes a light emitting device and may emit light. The light emitting area EA may have a concave portion. Referring to FIG. 11, a structure in which a left area and a right area of the light emitting area EA have a concave shape is disclosed, but is not limited thereto.

The contact area CT may be disposed in a concave portion of the light emitting area EA. That is, the contact area CT may be disposed to correspond to the concave shape of the light emitting area EA. The contact area CT may include a first contact area CT1, a second contact area CT2, a third contact area CT3 and a fourth contact area CT4. The first to fourth contact areas CT1 to CT4 may be spaced apart from each other. The first contact area CT1 and the third contact area CT3 are disposed in a left area of one sub-pixel SP, and the second contact area CT2 and the fourth contact area CT4 may be disposed in a right area of one sub-pixel SP, but are not limited thereto. In addition, a contact hole may be disposed in each of the first to fourth contact areas CT1 to CT4.

The cathode CAT may be disposed in the light emitting area EA. The cathode CAT includes a first cathode CAT1, a second cathode CAT2, a third cathode CAT3 and a fourth cathode CAT4. And, the first to fourth cathodes CAT1 to CAT4 may be disposed in one light emitting area EA. The first to fourth cathodes CAT1 to CAT4 may be sequentially arranged along the second direction Y. Specifically, in one light emitting area EA, the first cathode CAT1 may be disposed in an uppermost area of the light emitting area EA, and the fourth cathode CAT4 may be disposed in a lowermost area of the light emitting area EA, but the present disclosure is not limited thereto.

The first to fourth cathodes CAT1 to CAT4 may be spaced apart from each other by an opening OP. That is, the first to fourth cathodes CAT1 to CAT4 may be electrically separated from each other. In addition, the opening OP may overlap the light emitting area EA. The opening OP may be parallel to the first direction X, but is not limited thereto.

Each of the first to fourth cathodes CAT1 to CAT4 may extend from the light emitting area EA and may also be disposed in a partial area of the non-light emitting area NEA. In addition, the first cathode CAT1 overlaps the first contact area CT1, the second cathode CAT2 overlaps the second contact area CT2, the third cathode CAT3 overlaps the third contact area CT3, and the fourth cathode CAT4 overlaps the fourth contact area CT4. In addition, the first to fourth cathodes CAT1 to CAT4 may be formed to have the same area, but are not limited thereto.

The connection line CL may include a plurality of first connection lines CL1, a plurality of second connection lines CL2, a plurality of third connection lines CL3, and a plurality of fourth connection lines CL4. The plurality of first connection lines CL1 overlap the first cathode CAT1, the plurality of second connection lines CL2 overlap the second cathode CAT2, the plurality of third connection lines CL3 overlap the third cathode CAT3, and the plurality of fourth connection lines CL4 may overlap the fourth cathode CAT4.

One first connection line CL1 may overlap a plurality of first cathodes CAT1 disposed along the first direction X, one second connection line CL2 may overlap a plurality of second cathodes CAT2 disposed along the first direction X, one third connection line CL3 may overlap a plurality of third cathodes CAT3 disposed along the first direction X, and one fourth connection line CL4 may overlap a plurality of fourth cathodes CAT4 disposed along the first direction X.

The plurality of first connection lines CL1 may overlap the first contact area CT1, the plurality of second connection lines CL2 may overlap the second contact area CT2, the plurality of third connection lines CL3 may overlap the third contact area CT3, and the plurality of fourth connection lines CL4 may overlap the fourth contact area CT4.

That is, one sub-pixel SP may overlap one first connection line CL1, one second connection line CL2, one third connection line CL3, and one fourth connection line CL4.

The low potential voltage line EVSSL may supply a low potential voltage EVSS to the plurality of sub-pixels SP through the plurality of first connection lines CL1, the plurality of second connection lines CL2, the plurality of third connection lines CL3, and the plurality of fourth connection lines CL4. In detail, the first connection line CL1 may be electrically connected to the first cathode CAT1 through a contact hole of the first contact area CT1. The second connection line CL2 may be electrically connected to the second cathode CAT2 through a contact hole of the second contact area CT2. The third connection line CL3 may be electrically connected to the third cathode CAT3 through a contact hole of the third contact area CT3. The fourth connection line CL4 may be electrically connected to the fourth cathode CAT4 through a contact hole of the fourth contact region CT4.

That is, one sub-pixel SP may include a first cathode CAT1 receiving the low potential voltage EVSS from the first connection line CL1, a second cathode CAT2 receiving the low potential voltage EVSS from the second connection line CL2, a third cathode CAT3 receiving the low potential voltage EVSS from the third connection line CL3, and a fourth cathode CAT4 receiving the low potential voltage EVSS from the fourth connection line CL4.

Accordingly, even when at least one cathode of the first to fourth cathodes CAT1 to CAT4 is not normally driven, the sub-pixel SP may emit light through the remaining cathodes.

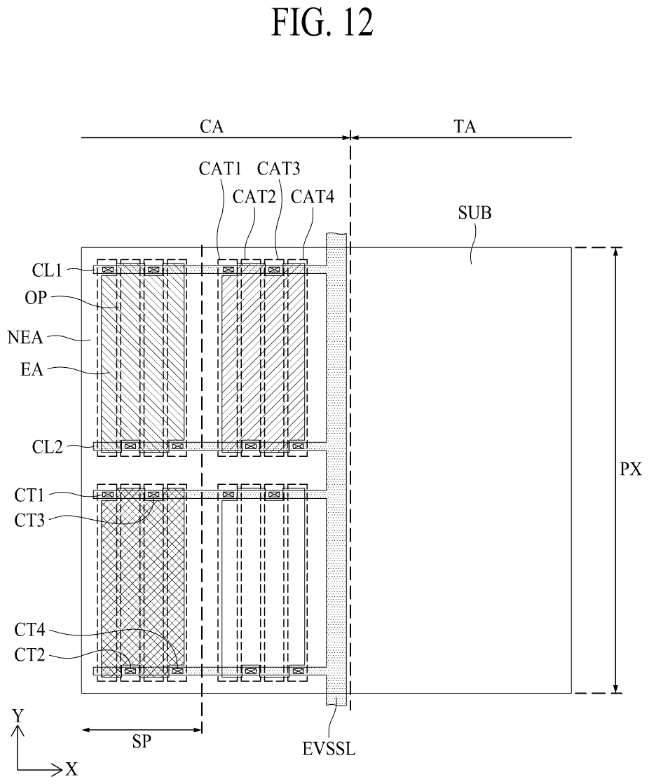

FIG. 12 is a plan view of the display device 10 according to a sixth example of the present disclosure.

Compared with the first to fourth cathodes CAT1 to CAT4 arranged along the second direction Y in the example of FIG. 11, the example of FIG. 12 discloses a structure in which the first to fourth cathodes CAT1 to CAT4 are arranged in the first direction X.

Referring to FIG. 12, a structure in which an upper area and a lower area of the light emitting area EA have a concave shape is disclosed, but is not limited to it.

The contact area CT may be disposed to correspond to the concave shape of the light emitting area EA. The contact area CT may include a first contact area CT1, a second contact area CT2, a third contact area CT3 and a fourth contact area CT4. The first to fourth contact areas CT1 to CT4 may be spaced apart from each other. The first contact area CT1 and the third contact area CT3 may be disposed in the upper area of the sub-pixel SP, and the second contact area CT2 and the fourth contact area CT4 may be disposed in the lower area of the sub-pixel SP, but are not limited thereto. In addition, a contact hole may be disposed in each of the first to fourth contact areas CT1 to CT4.

The cathode CAT may be disposed in the light emitting area EA. The cathode CAT may include a first cathode CAT1, a second cathode CAT2, a third cathode CAT3 and a fourth cathode CAT4. The first to fourth cathodes CAT1 to CAT4 may be sequentially arranged along the first direction X. Specifically, the first cathode CAT1 may be disposed in a left area of the light emitting area EA, and the fourth cathode CAT4 may be disposed in a right area of the light emitting area EA, but is not limited thereto.

The first to fourth cathodes CAT1 to CAT4 may be spaced apart from each other by the opening OP. That is, the first to fourth cathodes CAT1 to CAT4 may be electrically separated from each other. In addition, the opening OP may overlap the light emitting area EA. The opening OP may be parallel to the second direction Y, but is not limited thereto.

Each of the first to fourth cathodes CAT1 to CAT4 may extend from the light emitting area EA and may also be disposed in a partial area of the non-light emitting area NEA. In addition, the first cathode CAT1 overlaps the first contact area CT1, the second cathode CAT2 overlaps the second contact area CT2, the third cathode CAT3 overlaps the third contact area CT3, and the fourth cathode CAT4 overlaps the fourth contact area CT4. In addition, the first to fourth cathodes CAT1 to CAT4 may be formed to have the same area, but are not limited thereto.

The connection line CL may include a plurality of first connection lines CL1 and a plurality of second connection lines CL2. The plurality of first connection lines CL1 may overlap upper areas of the first to fourth cathodes CAT1 to CAT4, and the plurality of second connection lines CL2 may overlap lower areas of the first to fourth cathodes CAT1 to CAT4.

The plurality of first connection lines CL1 may overlap the first contact area CT1 and the third contact area CT3, and the plurality of second connection lines CL2 may overlap the second contact area CT2 and the fourth contact area CT4.

That is, one sub-pixel SP may overlap one first connection line CL1 and one second connection line CL2.

The low potential line EVSSL may supply the low potential voltage EVSS to the plurality of sub-pixels SP through the plurality of first connection lines CL1 and the plurality of second connection lines CL2. Specifically, the first connection line CL1 may be electrically connected to the first cathode CAT1 through a contact hole of the first contact area CT1, and may be electrically connected to the third cathode CAT3 through a contact hole of the third contact area CT3. In addition, the second connection line CL2 may be electrically connected to the second cathode CAT2 through a contact hole of the second contact area CT2, and may be electrically connected to the fourth cathode CAT4 through a contact hole of the fourth contact area CT4.

That is, one sub-pixel SP may include the first cathode CAT1 and the third cathode CAT3 receiving the low potential voltage EVSS from the first connection line CL1, and the second cathode CAT2 and the fourth cathode CAT4 receiving the low potential voltage EVSS from the second connection line CL2.

Accordingly, even when at least one cathode among the first to fourth cathodes CAT1 to CAT4 is not normally driven, the sub-pixel SP may emit light through the remaining cathodes. In addition, compared with the example of FIG. 11, the example of FIG. 12 may reduce the number of connection lines CL.

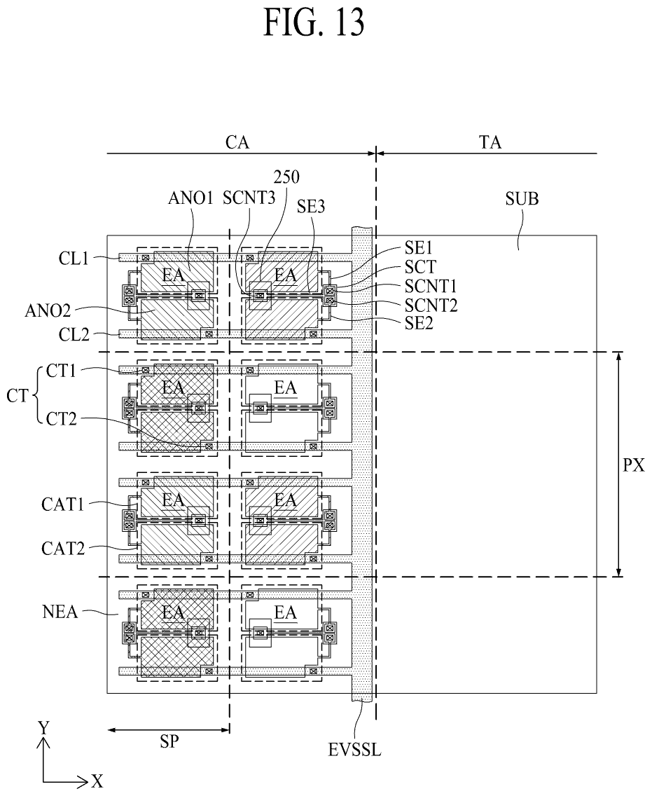

FIG. 13 is a plan view of the display device 10 according to a seventh example of the present disclosure.

Compared with FIGS. 2A-2C, except for the structure of the anode, FIG. 13 illustrates substantially the same structure as FIGS. 2A-2C. Accordingly, the same reference numerals are used for the same components as the display device illustrated in FIGS. 2A-2C, and repeated descriptions are omitted.

As described above, each of the plurality of sub-pixels SP may include the light emitting area EA, the non-light emitting area NEA, and the contact area CT. In addition, a light emitting device is disposed in the light emitting area EA, and the light emitting device may include an anode ANO, a light emitting layer, and a cathode CAT. FIG. 13 omits the configuration of the light emitting layer.

The anode ANO may be disposed in the light emitting area EA and may not be disposed in the contact area CT. The anode ANO may include a first anode ANO1 and a second anode ANO2. The first anode ANO1 may be disposed in an upper area of the light emitting area EA, and the second anode ANO2 may be disposed in a lower area of the light emitting area EA. The first anode ANO1 and the second anode ANO2 may be spaced apart from each other.

A sub-contact part SCT and a sub-electrode SE may be disposed in the non-light emitting area NEA. The sub-contact part SCT and the sub-electrode SE may include a conductive material. The sub-electrode SE may include a first sub-electrode SE1, a second sub-electrode SE2 and a third sub-electrode SE3.

One end of the first sub-electrode SE1 may be connected to the sub-contact part SCT, and the other end of the first sub-electrode SE1 may be connected to the first anode ANOL. The first sub-electrode SE1 may be formed by extending a partial area of the first anode ANO1, but is not limited thereto. In addition, the first anode ANO1 may be electrically connected to the sub-contact part SCT through a first sub-contact hole SCNT1, but is not limited thereto.

One end of the second sub-electrode SE2 may be connected to the sub-contact part SCT, and the other end of the second sub-electrode SE2 may be connected to the second anode electrode ANO2. The second sub-electrode SE2 may be formed by extending a partial area of the second anode electrode ANO2, but is not limited thereto. In addition, the second anode ANO2 may be electrically connected to the sub-contact part SCT through a second sub-contact hole SCNT2, but is not limited thereto.

One end of the third sub-electrode SE3 may be connected to the sub-contact part SCT, and the other end of the second sub-electrode SE2 may be connected to the drain electrode 250 of the thin film transistor 200. The third sub-electrode SE3 may be formed by extending a partial region of the sub-contact part SCT, but is not limited thereto. In addition, the third sub-electrode SE3 may be electrically connected to the drain electrode 250 through a third sub-contact hole SCNT3, but is not limited thereto.

In conclusion, the drain electrode 250 of the thin film transistor 200 may be electrically connected to the first anode ANO1 and the second anode ANO2 through the sub-contact part SCT and the sub-electrode SE.

That is, one sub-pixel SP may include the first anode ANO1 receiving a voltage from the first sub-electrode SE1 and the second anode ANO2 receiving a voltage from the second sub-electrode SE2. Accordingly, even when any one of the first anode ANO1 and the second anode ANO2 is not normally driven, the sub-pixel SP may emit light through the other one of first anode ANO1 and the second anode ANO2.

The cathode CAT may be disposed in the light emitting area EA. The cathode CAT may include a first cathode CAT1 and a second cathode CAT2. The first cathode CAT1 may overlap the first anode ANO1 and may not overlap the second anode ANO2. In addition, the second cathode CAT2 may overlap the second anode ANO2 and may not overlap the first anode ANO1.

The first cathode CAT1 may cover an entire surface of the first anode ANO1, and the second cathode CAT2 may cover an entire surface of the second anode ANO2. In addition, the first cathode CAT1 and the second cathode CAT2 may be spaced apart from each other by an opening OP.

As described above, one sub-pixel SP may include the first cathode CAT1 receiving the low potential voltage EVSS from the first connection line CL1 and the second cathode CAT2 receiving the low potential voltage EVSS from the second connection line CL2. Accordingly, even if any one of the first cathode CAT1 and the second cathode CAT2 is not normally driven, the sub-pixel SP may emit light through the other one of the first cathode CAT1 and the second cathode CAT2.

In conclusion, an example of FIG. 13 discloses a sub-pixel SP including the anode ANO including the first anode ANO1 and the second anode ANO2 and the cathode CAT including the first cathode CAT1 and the second cathode CAT2. Accordingly, even when one of the anodes ANO1 and ANO2 or the cathodes CAT1 and CAT2 is not normally driven, the sub-pixel SP may emit light through the other one of the anodes ANO1 and ANO2 or the other one of the cathodes CAT1 and CAT2. Accordingly, the sub-pixel SP may be more stably driven.

It will be apparent to those skilled in the art that the present disclosure described above is not limited by the above-described examples and the accompanying drawings and that various substitutions, modifications and variations can be made in the present disclosure without departing from the spirit or scope of the disclosures. Consequently, the scope of the present disclosure is defined by the accompanying claims, and it is intended that all variations or modifications derived from the meaning, scope and equivalent concept of the claims fall within the scope of the present disclosure.

1. A display device, comprising:
a plurality of pixels each including a circuit area and a transmission area, each pixel including a plurality of sub-pixels disposed in the circuit area;
a voltage line disposed in the circuit area and supplying a voltage; and
a plurality of connection lines disposed in the circuit area and electrically connected to the voltage line,
wherein each of the plurality of sub-pixels includes a first cathode and a second cathode spaced apart from each other, and
wherein the voltage line supplies the voltage to the first cathode through any one of the plurality of connection lines, and supplies the voltage to the second cathode through the other ones of the plurality of connection lines.

2. The display device of claim 1,
wherein each of the plurality of sub-pixels includes:
a first cathode area which is an area in which the first cathode is disposed, and
a second cathode area which is an area in which the second cathode is disposed,
wherein the first cathode area of each of the plurality of sub-pixels overlaps the circuit area, and does not overlap the transmission area, and
wherein the second cathode area of each of the plurality of sub-pixels overlaps the circuit area, and does not overlap the transmission area.

3. The display device of claim 1, wherein each of the plurality of sub-pixels includes a light emitting area and a contact area including a contact hole, and
wherein each of the first cathode and the second cathode overlaps the light emitting area and the contact area in each sub-pixel.

4. The display device of claim 3, wherein the contact area includes a first contact area and a second contact area spaced apart from each other,
wherein the first cathode overlaps the first contact area, and
wherein the second cathode overlaps the second contact area.

5. The display device of claim 4, wherein the plurality of connection lines includes a first connection line and a second connection line spaced apart from each other,
wherein the first connection line is in contact with the first cathode through a first contact hole in the first contact area, and
wherein the second connection line is in contact with the second cathode through a second contact hole in the second contact area.

6. The display device of claim 5, wherein the light emitting area includes a concave portion in which a partial area of the light emitting area has a concave shape, and
wherein the contact area is disposed in the concave portion.

7. The display device of claim 6, wherein the first connection line and the second connection line overlap the light emitting area.

8. The display device of claim 3, wherein each of the plurality of sub-pixels further includes a third cathode and a fourth cathode,
wherein the first to fourth cathode electrodes are spaced apart from each other by an opening,
wherein the first to fourth cathode electrodes are electrically separated from each other.

9. The display device of claim 8, wherein the first cathode and the second cathode are disposed in a first area of the light emitting area, and
wherein the third cathode and the fourth cathode are disposed in a second area of the light emitting area.

10. The display device of claim 9, wherein the contact area includes a first contact area and a second contact area spaced apart from each other,
wherein the first cathode and the second cathode overlap the first contact area, and
wherein the third cathode and the fourth cathode overlap the second contact area.

11. The display device of claim 10, wherein the plurality of connection lines includes a first connection line and a second connection line spaced apart from each other,
wherein the first connection line is in contact with the first cathode and the second cathode through a first contact hole of the first contact area, and
wherein the second connection line is in contact with the third cathode and the fourth cathode through a second contact hole of the second contact area.

12. The display device of claim 11, wherein the first connection line and the second connection line overlap the light emitting area.

13. The display device of claim 9, wherein the contact area includes a first contact area and a second contact area spaced apart from each other,
wherein each of the plurality of pixels includes a first sub-pixel and a second sub-pixel adjacent to the first sub-pixel in a first direction,
wherein any one of the first to fourth cathodes of the first sub-pixel and any one of the first to fourth cathodes of the second sub-pixel overlap the first contact area, and
wherein the other ones of the first to fourth cathodes of the first sub-pixel and the other ones of the first to fourth cathodes of the second sub-pixel overlap the second contact area.

14. The display device of claim 8, wherein the first to fourth cathodes are sequentially arranged from a first side of the light emitting area to a second side of the light emitting area.

15. The display device of claim 14, wherein the contact area includes a first contact area, a second contact area, a third contact area, and a fourth contact area spaced apart from each other, and
wherein the first cathode overlaps the first contact area, the second cathode overlaps the second contact area, the third cathode overlaps the third contact area, and the fourth cathode overlaps the fourth contact area.

16. The display device of claim 15, wherein the plurality of connection lines includes a first connection line and a second connection line spaced apart from each other,
wherein the first connection line is in contact with the first cathode through a first contact hole of the first contact area, and is in contact with the third cathode through a third contact hole of the third contact area, and
wherein the second connection line is in contact with the second cathode through a second contact hole of the second contact area, and is in contact with the fourth cathode through a fourth contact hole of the fourth contact area.

17. The display device of claim 15, wherein the plurality of connection lines includes a first connection line, a second connection line, a third connection line, and a fourth connection line spaced apart from each other, and
wherein the first connection line is in contact with the first cathode through a first contact hole in the first contact area,
wherein the second connection line is in contact with the second cathode through a second contact hole in the second contact area,
wherein the third connection line is in contact with the third cathode through a third contact hole in the third contact area, and
wherein the fourth connection line is in contact with the fourth cathode through a fourth contact hole in the fourth contact area.

18. The display device of claim 3, further comprising a first light emitting device including the first cathode and a second light emitting device including the second cathode in each of the plurality of sub-pixels,
wherein a first anode of the first light emitting device and a second anode of the second light emitting device are each electrically connected to a thin film transistor.

19. The display device of claim 18, wherein the first anode and the second anode are formed continuously.

20. The display device of claim 18, wherein the first anode and the second anode are spaced apart from each other,
wherein the first anode is electrically connected to the thin film transistor through a first sub-electrode, and
wherein the second anode is electrically connected to the thin film transistor through a second sub-electrode spaced apart from the first sub-electrode.

21. The display device of claim 8, wherein the plurality of connection lines includes a plurality of first connection line and a plurality of second connection line spaced apart from each other,
one of the plurality of first connection line overlaps a plurality of the first cathodes, a plurality of the second cathodes, a plurality of the third cathodes, and a plurality of the fourth cathodes, and
one of the plurality of second connection line overlaps a plurality of the first cathodes, a plurality of the second cathodes, a plurality of the third cathodes, and a plurality of the fourth cathodes.
